(19) United States
(12) Patent Application Publication
(10) Pub. No.: US 2012/0270411 A1
(43) Pub. Date: Oct. 25, 2012

(54) MANUFACTURING METHOD OF GATE DIELECTRIC LAYER

(75) Inventors: Kuo-Hui Su, Taipei City (TW); Yi-Nan Chen, Taipei City (TW); Hsien-Wen Liu, Taoyuan County (TW)

(73) Assignee: NANYA TECHNOLOGY CORPORATION, Taoyuan (TW)

(21) Appl. No.: 13/092,994

(22) Filed: Apr. 25, 2011

(51) Int. Cl. H01L 21/316

(52) U.S. Cl. 438/770; 257/E21.282

(57) ABSTRACT

A manufacturing method of a gate dielectric layer is provided. An oxidation treatment is performed to form an oxide layer on a substrate. A nitridation treatment is performed to form a nitride layer on the oxide layer. An annealing treatment is performed in a mixing gas of N₂ and O₂, where the temperature of the annealing treatment is 900° C. to 950° C., the pressure of the annealing treatment is 5 Torr to 10 Torr, and the content ratio of the N₂ to O₂ is 0.5 to 0.8.

### BACKGROUND OF THE INVENTION

1. Field of the Invention

The invention related to a manufacturing method of a dielectric layer and more particularly to a manufacturing method of a gate dielectric layer.

2. Description of Related Art

As the size of metal-oxide-semiconductor (MOS) transistors reduces gradually, the quality required for gate dielectric layers in MOS transistors becomes higher, and the demand for the interface characteristic between the gate dielectric layer and the substrate increases especially.

In the current gate dielectric layer fabrication, an oxidation treatment is usually performed to a substrate first to form an oxide layer on the substrate. Afterwards, a nitridation treatment is performed to form a nitride layer on the oxide layer. An annealing treatment is then performed in N₂ to stabilize characteristics of the layer formed. The oxide layer and the nitride layer then constitute a gate dielectric layer.

However, in the aforementioned annealing treatment, a portion of nitrogen in the nitride layer usually diffuses to the external environment which leads to a decrease in the dielectric constant of the gate dielectric layer. Additionally, the gate dielectric layer formed with the method above fails to satisfy the quality demanded for the gate dielectric layer. For example, an interface between the oxide layer and the substrate usually has defects such that the device performance is affected.

### SUMMARY OF THE INVENTION

The invention is directed to a manufacturing method of a gate dielectric layer. The manufacturing method is capable of forming a gate dielectric layer with high quality.

The invention is directed to a manufacturing method of a gate dielectric layer. Herein, an oxidation treatment is performed to form an oxide layer on a substrate. Afterwards, a nitridation treatment is performed to form a nitride layer on the oxide layer. An annealing treatment is then performed in a mixing gas of N₂ and O₂, where a temperature of the annealing treatment ranges from 900° C. to 950° C., a pressure of the annealing treatment ranges from 5 Torr to 10 Torr, and a content ratio of N₂ to O₂ ranges from 0.5 to 0.8.

According to an embodiment of the manufacturing method of the gate dielectric layer in the invention, a content ratio of N₂ to O₂ in the mixing gas is 0.625.

According to an embodiment of the manufacturing method of the gate dielectric layer in the invention, the oxidation treatment includes performing an in-situ steam generation (ISSG) process, for example.

According to an embodiment of the manufacturing method of the gate dielectric layer in the invention, the nitridation treatment includes performing a decoupled plasma nitridation (DPN) process, for example.

According an embodiment of the manufacturing method of the gate dielectric layer in the invention, an oxynitride layer is formed on the nitride layer during the annealing treatment.

In light of the foregoing, in the process of fabricating the gate dielectric layer in the invention, an annealing treatment is performed in a mixing gas of N₂ and O₂, such that nitrogen in the nitride layer is prevented from diffusing to the external environment which can lead to the decrease of the dielectric constant of the gate dielectric layer. Moreover, defects in the interface between the oxide layer and the substrate can be repaired.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate embodiments and, together with the description, serve to explain the principles of the invention.

FIG. 1 illustrates a flow chart for fabricating a gate dielectric layer in one embodiment of the invention.

FIG. 2 depicts a diagram comparing capacitance equivalent thicknesses of a gate dielectric layer in the present embodiment and a gate dielectric layer formed using the conventional technique.

FIG. 3 depicts a diagram comparing interface trap densities of a gate dielectric layer in the present embodiment and a gate dielectric layer formed using the conventional technique.

### DESCRIPTION OF EMBODIMENTS

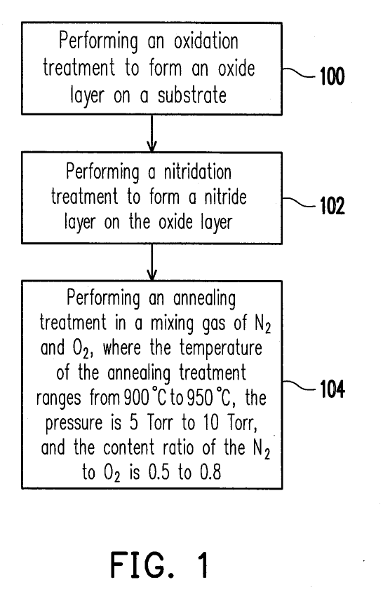

FIG. 1 illustrates a flow chart for fabricating a gate dielectric layer in one embodiment of the invention. Referring in FIG. 1, in step 100, an oxidation treatment is performed to a substrate to form an oxide layer on the substrate. The substrate is, for example, a silicon substrate. The oxidation treatment includes performing an in-situ steam generation (ISSG) process, for instance. The oxide layer formed has a thickness less than 25 angstrom, for example.

Afterwards, in step 102, a nitridation treatment is performed to form a nitride layer on the oxide layer. The nitridation treatment includes, for example, performing a decoupled plasma nitridation process. As commonly known by persons skilled in the art, the nitridation treatment is usually a low-temperature treatment. In order to enhance the stability of the layer formed, a thermal treatment is further carried out after the nitridation treatment.

In step 104, an annealing treatment is performed in a mixing gas of N₂ and O₂ to increase the stability of the layer formed. In the present embodiment, a temperature of the annealing treatment ranges from 900° C. to 950° C. and a pressure of the annealing treatment ranges from 5 Torr to 10 Torr. Additionally, in the mixing gas, a content ratio of N₂ to O₂ ranges from 0.5 to 0.8 and is preferably 0.625.

It should be noted that an oxynitride layer is formed on the nitride layer during the annealing treatment. The oxynitride layer, the nitride layer and the oxide layer then constitute the gate dielectric layer.

In the present embodiment, as the annealing treatment is performed after the nitridation treatment, the stability of the layer formed can be enhanced effectively.

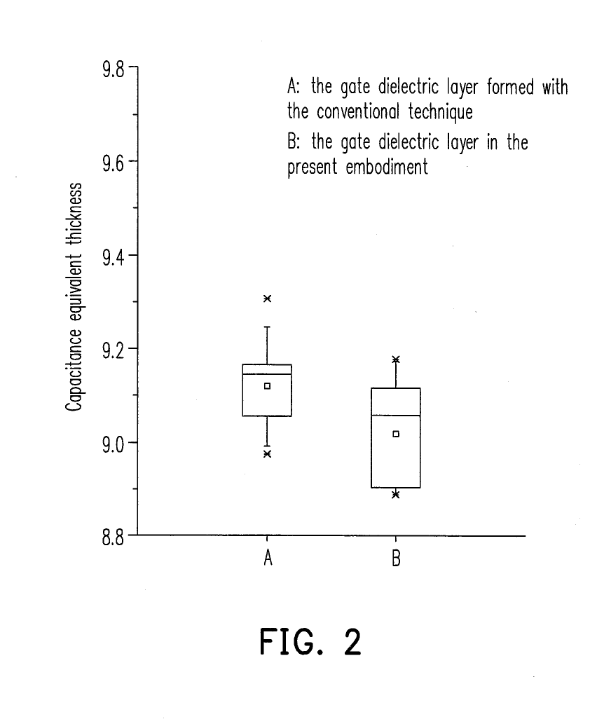

Since the annealing treatment is performed in a mixing gas of N₂ and O₂ having a content ratio ranging from 0.5 to 0.8, the oxynitride layer is formed on the nitride layer during the annealing treatment. As a consequence, the oxynitride layer is capable of effectively preventing the nitrogen in the nitride layer from diffusing to the external environment during the annealing treatment which leads to the decrease in the dielectric constant of the gate dielectric layer. As depicted in FIG. 2, the gate dielectric layer formed after the annealing treatment performed in a mixing gas of N₂ and O₂ with a content ratio ranging from 0.5 to 0.8 (the present embodiment) can have a higher dielectric constant. Therefore, under the same condition, the capacitance equivalent thickness (CET) of the gate dielectric layer in the present embodiment is lower than the CET of the gate dielectric layer formed with the conventional technique (where the annealing treatment is performed merely in N₂).

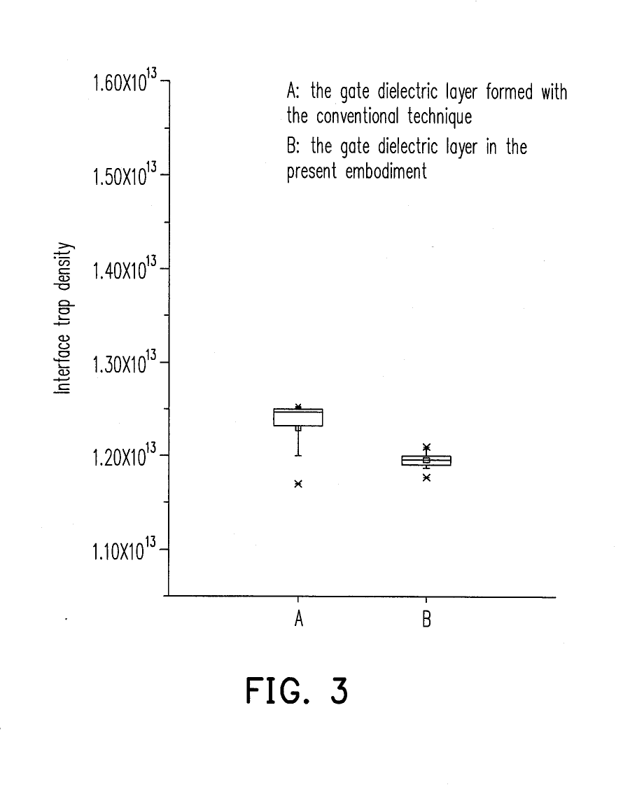

Further, as the annealing treatment aforementioned is performed in a mixing gas of N₂ and O₂ with a content ratio ranging from 0.5 to 0.8, and oxygen can pass through the oxynitride layer, the nitride layer, and the oxide layer to repair the defects in the interface between the oxide layer and the substrate, the interface trap density (Dit) of the gate dielectric layer in the present embodiment can be lower than the Dit of the gate dielectric layer formed using the conventional technique, as illustrated in FIG. 3.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A manufacturing method of a gate dielectric layer, the manufacturing method comprising:
performing an oxidation treatment to form an oxide layer on a substrate;
performing a nitridation treatment to form a nitride layer on the oxide layer; and
performing an annealing treatment in a mixing gas of N₂ and O₂, wherein a temperature of the annealing treatment ranges from 900° C. to 950° C., a pressure of the annealing treatment ranges from 5 Torr to 10 Torr, and a content ratio of N₂ to O₂ ranges from 0.5 to 0.8.

2. The manufacturing method of the gate dielectric layer as claimed in claim 1, wherein a content ratio of N₂ to O₂ in the mixing gas is 0.625.

3. The manufacturing method of the gate dielectric layer as claimed in claim 1, wherein the oxidation treatment comprises an in-situ steam generation process.

4. The manufacturing method of the gate dielectric layer as claimed in claim 1, wherein the oxidation treatment comprises a decoupled plasma nitridation process.

5. The manufacturing method of the gate dielectric layer as claimed in claim 1, wherein an oxynitride layer is formed on the nitride layer during the annealing treatment.
